(19) United States
(12) Patent Application Publication
(10) Pub. No.: US 2025/0251289 A1
(43) Pub. Date: Aug. 7, 2025

(54) SYSTEM AND METHOD FOR ONLINE DETECTION OF JUNCTION TEMPERATURE OF SEMICONDUCTOR DEVICE, AND CONTROLLER

(71) Applicants: Xi'an Jiaotong University, Xi'an (CN); Shaoxing Tongyue Wide Bandgap Semiconductor Research Institute, Shaoxing (CN)

(72) Inventors: Laili WANG, Shaoxing (CN); Xiaoliang SHE, Shaoxing (CN); Fengtao YANG, Shaoxing (CN); Zizhen CHENG, Xi'an (CN); Hang KONG, Shaoxing (CN); Zhiqiang ZHAO, Shaoxing (CN)

(73) Assignees: Xi'an Jiaotong University, Xi'an (CN); Shaoxing Tongyue Wide Bandgap Semiconductor Research Institute, Shaoxing (CN)

(21) Appl. No.: 18/763,597

(22) Filed: Jul. 3, 2024

Related U.S. Application Data
(63) Continuation of application No. PCT/CN2024/080389, filed on Mar. 6, 2024.

(30) Foreign Application Priority Data
Feb. 5, 2024 (CN) 2024101652735

(51) Int. Cl. G01K 7/01

(52) U.S. Cl. CPC G01K 7/015

(57) ABSTRACT

Disclosed are a system and method for online detection of a junction temperature of a semiconductor device, and a controller. The system includes a controller, an online measurement circuit, and a detection module configured to extract saturated drain current information of a device under test; one end of the online measurement circuit is connected to a drain of the device under test; the other end of the online measurement circuit is connected to a source of the device under test; when the device under test enters a saturation region to operate, an energy storage element in the online measurement circuit spontaneously injects current into the drain of the device under test, so that the drain current of the device under test rises; the controller determines the junction temperature of the device under test according to the saturated drain current information of the device under test extracted by the detection module.

### CROSS-REFERENCE TO RELATED APPLICATIONS

The application claims priority to Chinese patent application No. 2024101652735, filed on Feb. 5, 2024, the entire contents of which are incorporated herein by reference.

### TECHNICAL FIELD

The present disclosure belongs to the field of online technology, and relates to a system and method for online detection of a junction temperature, and a controller, in particular to a system and method for online detection of a junction temperature of a semiconductor device, and a controller.

### BACKGROUND

Semiconductor devices often play a core role in the application of power electronics technology as power electronic devices that can realize power conversion and control, so the reliability of semiconductor devices will seriously affect the operation reliability of the whole power system. In recent years, with the increasingly stringent requirements for the application environment of semiconductor devices in important fields such as oil exploration, new energy vehicles and aerospace, the traditional silicon (Si)-based power devices cannot meet the requirements since the material characteristics are approaching the limit, and a new generation of wide bandgap (silicon carbide (SiC), gallium nitride (GaN), etc.) and ultra-wide bandgap (diamond, gallium oxide, etc.) power semiconductor devices are gradually replacing the traditional Si-based power devices. However, due to the differences in material characteristics, compared with traditional Si-based power devices, wide bandgap and ultra-wide bandgap power semiconductor devices need more advanced reliability testing and evaluation methods. For example, SiC MOSFET devices theoretically have a wide temperature operating range of 600° C., but smaller device area will lead to greater heat flux, which will lead to problems such as excessive junction temperature or fluctuation, thus placing more stringent requirements on thermal management. Current research has shown that more than 50% of semiconductor device failures are caused by overheating due to excessive junction temperature or fluctuation. If the junction temperature is too high or fluctuates too much, the turn-on voltage and leakage current of the device will increase, so that the loss of the device in the switching transient state and the on state will increase. In addition, the increase of thermal mechanical stress will also be caused, which will further easily lead to the failure of the semiconductor device, so that the reliability of the semiconductor device is seriously threatened. Thus, a low-cost, high-precision, high-sensitivity, and high-response-speed online junction temperature detection method is important for reliability evaluation, state measurement, and health management of semiconductor devices in operation.

There are four traditional methods to detect the junction temperature of semiconductor devices: physical contact measurement method, optical non-contact measurement method, thermal impedance model prediction method and thermal sensitive electrical parameter method. The physical contact measurement method is to directly place a thermal resistor or a thermocouple inside the device, so as to obtain a measured junction temperature inside the device. Although the principle of this method is simple, there is a big error between the measured value and the real value, and the method is strong in invasiveness and slow in response, thus being not suitable for online measurement; although the optical non-contact measurement method is high in precision, the method requires a corresponding optical processing process, and is subject to a large limitation; the thermal impedance model prediction method can inversely calculate the junction temperature of the device through real-time loss and a transient thermal impedance network model, but it is very difficult to calculate the loss in real time and establish thermal impedance model, and the parameters of thermal impedance model will change significantly with the aging of the device, which will have a great impact on the accuracy of the results. Compared with the above three methods, the thermal sensitive electrical parameter method measures the junction temperature of the device by using the varying relationship of the electrical parameter of the device with the temperature. This method not only has high measurement accuracy and fast response speed, but also does not need to change the original device package structure, and has been widely used for online junction temperature measurement of conventional Si-based power devices. However, due to the stable electrical properties and strong thermal stability of semiconductor materials in high temperature environment, thermal sensitivity of the semiconductor device is low. In addition, for wide bandgap and ultra-wide bandgap semiconductor devices, the devices have wider band gap, higher switching frequency, higher power density, wider temperature range and faster operating speed, which will lead to lower temperature sensitivity and greater measurement error of the traditional thermal sensitive electrical parameter method, so it is necessary to use a high-precision and high-bandwidth circuit to measure the traditional thermal sensitive electrical parameters, but this will greatly increase the difficulty and cost of online detection of the junction temperature of semiconductor devices.

### SUMMARY

It is an object of the present disclosure to overcome the above-mentioned disadvantages of the prior art, and to provide a system and method for online detection of a junction temperature of a semiconductor device, and a controller, which are capable of detecting the junction temperature of the semiconductor device online, and has the characteristics of low cost, high precision, high sensitivity and high response speed.

To achieve the above object, disclosed is a system for online detection of a junction temperature of a semiconductor device, including a controller, an online measurement circuit, and a detection module configured to extract saturated drain current information of a device under test, wherein one end of the online measurement circuit is connected to a drain of the device under test, and the other end of the online measurement circuit is connected to a source of the device under test;

when the device under test enters a saturation region to operate, an energy storage element in the online measurement circuit spontaneously injects current into the drain of the device under test, so that the drain current of the device under test rises;

the controller is connected to the detection module, and determines the junction temperature of the device under test according to the saturated drain current information of the device under test extracted by the detection module.

Further, the system for online detection of a junction temperature of a semiconductor device further includes a driving voltage control circuit, wherein one end of the driving voltage control circuit is connected to a gate of the device under test, the other end of the driving voltage control circuit is connected to a Kelvin source of the device under test, a control end of the driving voltage control circuit is connected to the controller, and the controller controls the driving voltage control circuit to output a driving voltage signal to the device under test, so that the device under test enters the saturation region to operate.

Further, the online measurement circuit includes an energy storage element, a direct current (DC) voltage source, a controllable switching device and a device with a unidirectional blocking function, wherein one end of the device with a unidirectional blocking function is connected to the drain of the device under test, the other end of the device with a unidirectional blocking function is connected to one end of the energy storage element and one end of the controllable switching device, the other end of the controllable switching device is connected to a positive pole of the DC voltage source, and a negative pole of the DC voltage source and the other end of the energy storage element are connected to the source of the device under test.

Further, the online measurement circuit includes an energy storage element, a pulsed DC source and a device with a unidirectional blocking function, wherein one end of the device with a unidirectional blocking function is connected to the drain of the device under test, the other end of the device with a unidirectional blocking function is connected to one end of the energy storage element and a positive pole of the pulsed DC source, and a negative pole of the pulsed DC source and the other end of the energy storage element are connected to the source of the device under test.

Further, the online measurement circuit includes an energy storage element and a device with a unidirectional blocking function, wherein one end of the device with a unidirectional blocking function is connected to the drain of the device under test, the other end of the device with a unidirectional blocking function is connected to one end of the energy storage element, and the other end of the energy storage element is connected to the source of the device under test.

Further, the energy storage element is a capacitor.

In addition, disclosed is a method for online detection of a junction temperature of a semiconductor device, including:
enabling the device under test to enter the saturation region to operate, and injecting, by the energy storage element in the online measurement circuit, current into the drain of the device under test spontaneously after the device under test enters the saturation region to operate, so that the drain current of the device under test rises;
extracting the saturated drain current information of the device under test by the detection module; and
determining the junction temperature of the device under test according to the saturated drain current information of the device under test.

Further, the system for online detection of a junction temperature of a semiconductor device further includes a driving voltage control circuit, wherein one end of the driving voltage control circuit is connected to the gate of the device under test, the other end of the driving voltage control circuit is connected to the Kelvin source of the device under test, and a control end of the driving voltage control circuit is connected to the controller.

Further, the method for online detection of a junction temperature of a semiconductor device specifically includes:
1) in the t0-t1 stage, a gate-source voltage VGS of the device under test is less than a threshold voltage, so that the device under test is in an off state, indicating that the drain current ID flowing into the device under test is zero;
2) in the t1-t2 stage, the driving voltage control circuit outputs a first driving voltage signal to the device under test, resulting in the gate-source voltage VGS of the device under test being higher than the threshold voltage, so that the device under test is in a normal on state, indicating that the drain current ID flowing into the device under test rises;
3) in the t2-t3 stage, the gate-source voltage VGS of the device under test is less than the threshold voltage, so that the device under test changes from the on state to the off state, indicating that the drain current ID flowing into the device under test is zero;
4) in the t3-t4 stage, the gate-source voltage VGS of the device under test is less than the threshold voltage, so that the device under test continues to be maintained in the off state, indicating that the drain current ID flowing into the device under test is zero, in which case an energy storage element charging control signal VM is activated for charging the energy storage element in the online measurement circuit;
5) in the t4-t5 stage, the energy storage element in the online measurement circuit has started to be charged, so that the energy storage element charging control signal VM is deactivated; the gate-source voltage VGS of the device under test is less than the threshold voltage, so that the device under test continues to be maintained in the off state, indicating that the drain current ID flowing into the device under test is zero;
6) in the t5-t6 stage, the driving voltage control circuit outputs a second driving voltage signal, so that a voltage between the drain and the source (i.e., a drain-source voltage) of the device under test gradually drops from a DC bus voltage to a voltage across the energy storage element in the online measurement circuit, and the drain current flowing into the device under test rises; the energy storage element charging control signal VM is not activated;
7) in the t6-t7 stage, the driving voltage control circuit outputs the second driving voltage signal to the device under test, and since the voltage across the energy storage element is higher than a voltage between the gate and the Kelvin source of the device under test, the device under test enters the saturation region to operate, and the energy storage element in the online measurement circuit starts to spontaneously inject current into the drain of the device under test, so that the drain current of the device under test rises; the saturated drain current information of the device under test is extracted by the detection module, and the junction temperature of the device under test is determined according to the saturated drain current information of the device under test;
8) in the t7-t8 stage, the gate-source voltage VGS of the device under test is less than the threshold voltage, so that the device under test enters the off state, indicating that the drain current ID flowing into the device under test is zero; the energy storage element charging control signal VM is not activated.

In addition, disclosed is a controller, including:
a control module, configured to enable a device under test to enter a saturation region to operate, and inject, by an energy storage element in an online measurement circuit, current into a drain of the device under test spontaneously after the device under test enters the saturation region to operate, so that the drain current of the device under test rises;
an extracting module, configured to extract saturated drain current information of the device under test by a detection module; and
a determining module, configured to determine the junction temperature of the device under test according to the saturated drain current information of the device under test.

The present disclosure has the following beneficial effects:
during the concrete operation of the system and method for online detection of a junction temperature of a semiconductor device, and the controller according to the present disclosure, since the saturated drain current information of the device under test in the saturation region has very high temperature sensitivity under the synergistic effect of the threshold voltage, the on-resistance and the voltage between the drain and the source, the present disclosure performs high-precision, high-sensitivity, high-response-speed and low-cost online detection on the junction temperature of the device under test by extracting the saturated drain current information of the device under test, so that the operation is convenient and simple, and the practicability is strong.

### BRIEF DESCRIPTION OF DRAWINGS

FIG. 1 is a schematic diagram of factors affecting the temperature sensitivity of saturated drain current in an embodiment of the present disclosure;

FIG. 2 is a structural schematic diagram of a system for online detection of a junction temperature of a semiconductor device in Embodiment 1;

FIG. 3 is an operation timing diagram of a method for online detection of a junction temperature of a semiconductor device in Embodiment 6;

FIG. 4 is a comparison diagram of current changes in online detection of the junction temperature of a semiconductor device in Embodiment 6;

FIG. 5 is a structural schematic diagram of an online measurement circuit 200 in Embodiment 2;

FIG. 6 is a structural schematic diagram of an online measurement circuit 200 in Embodiment 3; and

FIG. 7 is a structural schematic diagram of an online measurement circuit 200 in Embodiment 4.

### DETAILED DESCRIPTION OF THE EMBODIMENTS

In order to enable those skilled in the art to better understand the solutions of the present disclosure, the technical solutions in the embodiments of the present disclosure will be clearly and completely described below in conjunction with the accompanying drawings in the embodiments of the present disclosure. It is obvious that the described embodiments are only some embodiments of a part of the present disclosure, not all embodiments, and are not intended to limit the scope of the disclosure of the present disclosure. Additionally, in the following description, descriptions of well-known structures and techniques are omitted to avoid unnecessarily obscuring the concepts disclosed herein. Based on the embodiments in the present disclosure, all other embodiments obtained by those of ordinary skill in the art without making inventive labor should belong to the scope of protection of the present disclosure.

Structural schematic diagrams according to embodiments disclosed by the present disclosure are shown in the accompanying drawings. The figures are not drawn to scale, with certain details exaggerated and may have been omitted for purposes of clarity of presentation. The shapes of various regions and layers shown in the figure, as well as their relative sizes and positional relationships, are only exemplary, and may actually be deviated due to manufacturing tolerances or technical limitations, and those skilled in the art can additionally design regions/layers with different shapes, sizes and relative positions according to actual needs.

### Embodiment 1

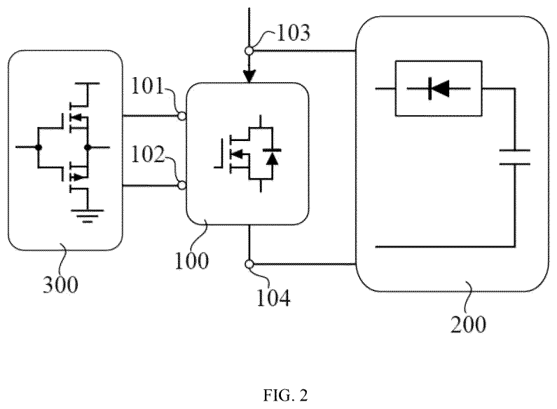

Referring to FIG. 2, a system for online detection of a junction temperature of a semiconductor device according to the present disclosure includes a controller, an online measurement circuit 200, and a detection module configured to extract saturated drain current information of a device under test 100, wherein one end of the online measurement circuit 200 is connected to a drain 103 of the device under test 100, the other end of the online measurement circuit 200 is connected to a source 104 of the device under test 100, and the controller is connected to the detection module.

During operation, when the device under test 100 enters a saturation region to operate, an energy storage element 204 in the online measurement circuit 200 spontaneously injects current into the drain 103 of the device under test 100, so that the drain current of the device under test 100 rises; the controller determines the junction temperature of the device under test 100 according to the saturated drain current information of the device under test 100 extracted by the detection module.

Further, a driving voltage control circuit 300 is further included in this embodiment, wherein one end of the driving voltage control circuit 300 is connected to a gate 101 of the device under test 100, the other end of the driving voltage control circuit 300 is connected to a Kelvin source 102 of the device under test 100, a control end of the driving voltage control circuit 300 is connected to the controller, and the controller controls the driving voltage control circuit 300 to output a driving voltage signal to the device under test 100, so that the device under test 100 enters the saturation region to operate.

During operation, the driving voltage control circuit 300 outputs a driving voltage signal to the device under test 100, so that on the one hand, the turn-on or turn-off of the device under test 100 can be controlled, on the other hand, the value of the maximum saturated current flowing into the device under test 100 can be adjusted by regulating the voltage between the gate 101 and the Kelvin source 102 of the device under test 100, thereby controlling the additional error introduced by the present disclosure. Since the saturated drain current information of the device under test 100 in the saturation region has very high temperature sensitivity under the synergistic effect of the threshold voltage, the on-resistance and the voltage between the drain 103 and the source 104, the present disclosure performs high-precision, high-sensitivity, high-response-speed and low-cost online detection on the junction temperature of the device under test 100 by extracting the saturated drain current information of the device under test 100.

In this embodiment, the device under test 100 includes, but is not limited to, semiconductor devices such as Si IGBT devices, SiC MOSFETs, and GaN devices.

In this embodiment, the energy storage element 204 is a capacitor.

In this embodiment, the detection module uses a direct measurement method, an indirect measurement method or an alternative measurement method to extract the saturated drain current information of the device under test 100, i.e., the saturated drain current information may be a saturated drain current value or a physical quantity associated with the saturated drain current value.

### Embodiment 2

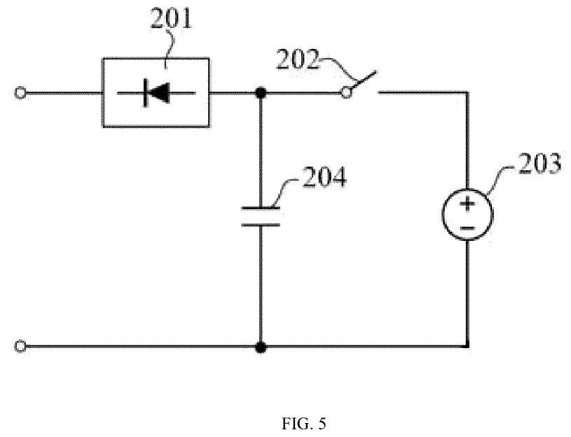

Referring to FIG. 5, on the basis of Embodiment 1, the online measurement circuit 200 includes an energy storage element 204, a DC voltage source 203, a controllable switching device 202 and a device with a unidirectional blocking function 201, wherein one end of the device with a unidirectional blocking function 201 is connected to the drain 103 of the device under test 100, the other end of the device with a unidirectional blocking function 201 is connected to one end of the energy storage element 204 and one end of the controllable switching device 202, the other end of the controllable switching device 202 is connected to a positive pole of the DC voltage source 203, and a negative pole of the DC voltage source 203 and the other end of the energy storage element 204 are connected to the source 104 of the device under test 100.

It should be noted that the function of the device with a unidirectional blocking function 201 is to prevent a high voltage between the drain 103 and the source 104 of the device under test 100 in the power loop from being applied to the energy storage element 204 and other elements in the online measurement circuit 200, resulting in element damage and safety problems. The function of the DC voltage source 203 is to provide electrical energy to the energy storage element 204, and the function of the controllable switching device 202 is to control the DC voltage source 203 to charge the energy storage element 204.

### Embodiment 3

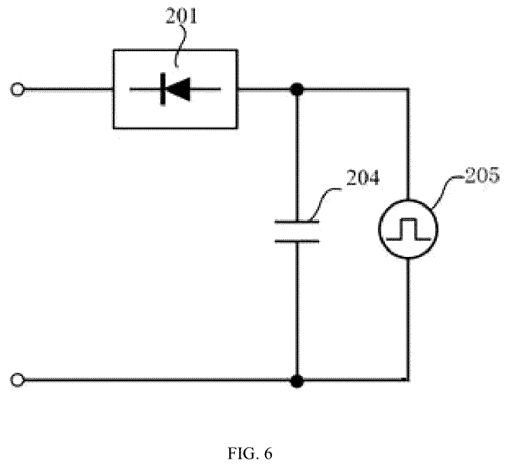

Referring to FIG. 6, on the basis of Embodiment 1, in this embodiment, the online measurement circuit 200 includes an energy storage element 204, a pulsed DC source 205 and a device with a unidirectional blocking function 201, wherein one end of the device with a unidirectional blocking function 201 is connected to the drain 103 of the device under test 100, the other end of the device with a unidirectional blocking function 201 is connected to one end of the energy storage element 204 and a positive pole of the pulsed DC source 205, and a negative pole of the pulsed DC source 205 and the other end of the energy storage element 204 are connected to the source 104 of the device under test 100.

It should be noted that the function of the device with a unidirectional blocking function 201 is to prevent a high voltage between the drain 103 and the source 104 of the device under test 100 in the power loop from being applied to the energy storage element 204 in the online measurement circuit 200, resulting in element damage and safety problems. Electrical energy is provided to the energy storage element 204 by the pulsed DC source 205.

### Embodiment 4

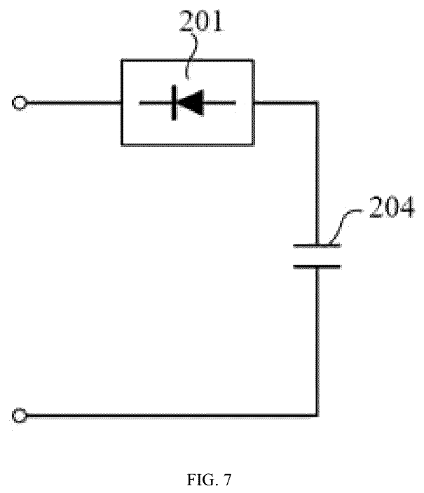

Referring to FIG. 7, the online measurement circuit 200 includes an energy storage element 204 and a device with a unidirectional blocking function 201, wherein one end of the device with a unidirectional blocking function 201 is connected to the drain 103 of the device under test 100, the other end of the device with a unidirectional blocking function 201 is connected to one end of the energy storage element 204, and the other end of the energy storage element 204 is connected to the source 104 of the device under test 100.

It should be noted that the device with a unidirectional blocking function 201 can prevent a high voltage between the drain 103 and the source 104 of the device under test 100 in the power loop from being applied to the energy storage element 204, resulting in element damage and safety problems.

### Embodiment 5

Correspondingly, disclosed is a method for online detection of a junction temperature of a semiconductor device, which is based on the system for online detection of a junction temperature of a semiconductor device. The system includes a controller, an online measurement circuit 200, and a detection module configured to extract saturated drain current information of a device under test 100, wherein one end of the online measurement circuit 200 is connected to a drain 103 of the device under test 100, the other end of the online measurement circuit 200 is connected to a source 104 of the device under test 100, and the controller is connected to the detection module.

The method for online detection of a junction temperature of a semiconductor device includes:
enabling, by the controller, the device under test 100 to enter the saturation region to operate, and injecting, by the energy storage element 204 in the online measurement circuit 200, current into the drain 103 of the device under test 100 spontaneously after the device under test 100 enters the saturation region to operate, so that the drain current of the device under test 100 rises;
extracting, by the controller, the saturated drain current information of the device under test 100 by the detection module; and
determining, by the controller, the junction temperature of the device under test 100 according to the saturated drain current information of the device under test 100.

### Embodiment 6

In order to enable the device under test 100 to operate in the saturation region, the system for online detection of a junction temperature of a semiconductor device further includes a driving voltage control circuit 300, wherein one end of the driving voltage control circuit 300 is connected to a gate 101 of the device under test 100, the other end of the driving voltage control circuit 300 is connected to a Kelvin source 102 of the device under test 100, and a control end of the driving voltage control circuit 300 is connected to the controller.

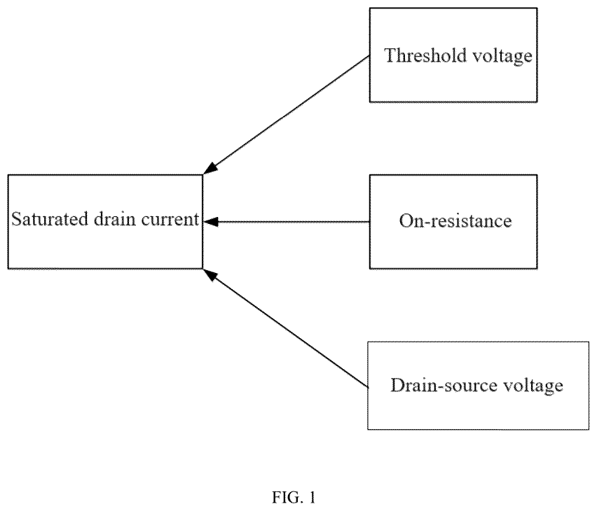

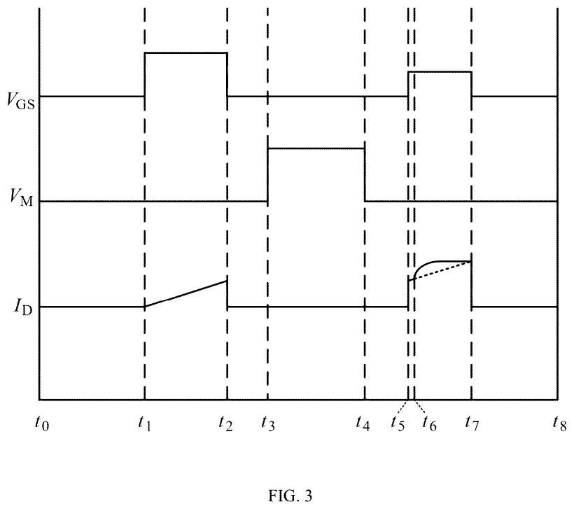

Correspondingly, referring to FIG. 1 and FIG. 3, this embodiment further discloses a method for online detection of a junction temperature of a semiconductor device, including the following steps:
1) in the t0-t1 stage, a gate-source voltage VGS of the device under test 100 is less than a threshold voltage of the device under test 100, so that the device under test 100 is in an off state, indicating that the drain current ID flowing into the device under test 100 is zero, in which case an energy storage element charging control signal VM is not activated;
2) in the t1-t2 stage, the driving voltage control circuit 300 outputs a first driving voltage signal and sends the first driving voltage signal to the device under test 100, resulting in the gate-source voltage VGS of the device under test 100 being higher than the threshold voltage, so that the device under test 100 is in a normal on state, wherein taking an inductive load as an example, the drain current ID flowing into the device under test 100 exhibits a linear rise, in which case the energy storage element charging control signal VM is still not activated;
3) in the t2-t3 stage, the gate-source voltage VGS of the device under test 100 is less than the threshold voltage, so that the device under test 100 changes from the on state to the off state, indicating that the drain current ID flowing into the device under test 100 is zero, in which case the energy storage element charging control signal VM is still not activated;
4) in the t3-t4 stage, the gate-source voltage VGS of the device under test 100 is less than the threshold voltage, so that the device under test 100 continues to be maintained in the off state, indicating that the drain current ID flowing into the device under test 100 is zero, in which case the energy storage element charging control signal VM is activated for charging the energy storage element 204 in the online measurement circuit 200, so as to prepare for the subsequent spontaneous injection of current into the drain 103 of the device under test 100 by the energy storage element 204;
5) in the t4-t5 stage, the energy storage element 204 in the online measurement circuit 200 has started to be charged, so that the energy storage element charging control signal VM is deactivated; the gate-source voltage VGS of the device under test 100 is less than the threshold voltage, so that the device under test 100 continues to be maintained in the off state, indicating that the drain current ID flowing into the device under test 100 is zero;
6) in the t5-t6 stage, the driving voltage control circuit 300 outputs a second driving voltage signal, so that a voltage between the drain 103 and the source 104 of the device under test 100 gradually drops from a DC bus voltage to a voltage across the energy storage element 204 in the online measurement circuit 200, and the drain current flowing into the device under test 100 rises; the energy storage element charging control signal VM is not activated;
7) in the t6-t7 stage, the driving voltage control circuit 300 outputs the second driving voltage signal to the device under test 100, and since the voltage across the energy storage element 204 is higher than a voltage between the gate 101 and the Kelvin source 102 of the device under test 100, the device under test 100 enters the saturation region to operate, and the energy storage element 204 in the online measurement circuit 200 starts to spontaneously inject current into the drain 103 of the device under test 100, so that the drain current of the device under test 100 rises; the saturated drain current information of the device under test 100 is extracted, and the junction temperature of the device under test 100 is determined according to the saturated drain current information of the device under test 100;
8) in the t7-t8 stage, the gate-source voltage VGS of the device under test 100 is less than the threshold voltage, so that the device under test 100 enters the off state, indicating that the drain current ID flowing into the device under test 100 is zero; the energy storage element charging control signal VM is not activated. By now, one cycle ends.

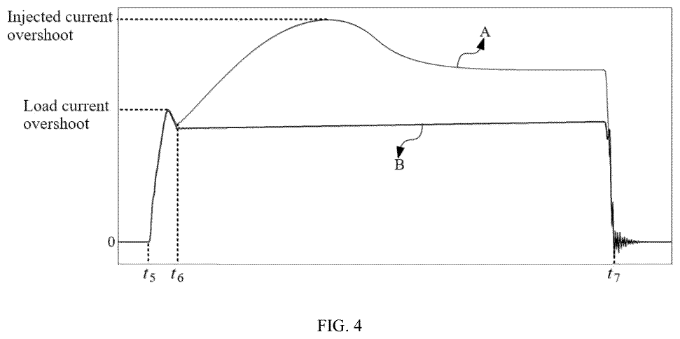

Referring to FIG. 4, the present disclosure compares the load current B with the injected saturated drain current A by an example. It can be seen that the extra current injected into the device under test 100 does not affect the load current B under normal operating conditions. In addition, it can also be found that the saturated drain current A flowing into the device under test 100 has high temperature sensitivity, which verifies the correctness and feasibility of the present disclosure.

### Embodiment 7

On the basis of Embodiment 5, disclosed is a controller, including:
a control module, configured to enable a device under test 100 to enter a saturation region to operate, and inject, by an energy storage element 204 in an online measurement circuit 200, current into a drain 103 of the device under test 100 spontaneously after the device under test 100 enters the saturation region to operate, so that the drain current of the device under test 100 rises;
an extracting module, configured to extract saturated drain current information of the device under test 100 by a detection module; and
a determining module, configured to determine the junction temperature of the device under test 100 according to the saturated drain current information of the device under test 100.

It should be noted that the present disclosure has the following characteristics:
higher temperature sensitivity
a, after the device under test 100 enters the saturation region to operate, the energy storage element 204 in the online measurement circuit 200 will spontaneously inject current into the drain 103 of the device under test 100. Due to the synergistic feedback effect of the temperature sensitivity of the threshold voltage, the on-resistance and the voltage between the drain 103 and the source 104 to the saturated drain current information, the relationship between the drain current of the device under test 100 and the temperature exhibits a segmented and highly linear characteristic.
b, compared with the thermal sensitive electrical parameter methods using other temperature sensitive parameters, the present disclosure has the advantages of low cost, high precision, high sensitivity, high response speed and the like. The temperature sensitivity of the existing thermal sensitive electrical parameter methods using other temperature sensitive parameters is low, while the temperature sensitivity of the present disclosure can reach hundreds or even hundreds of billions of times that of other methods.

### Low Interference to Normal Operating Conditions

a, the extra current injected into the device under test 100 does not affect the load current under operating conditions; although the load current and the extra injected current will converge in the device under test 100, they will not affect each other.
b, the power loss introduced after the extra current is injected into the device under test 100 is substantially consistent with the rated turn-on transient loss provided in the data sheet of the device under test 100. In practical application, since the temperature sampling frequency is low and the losses are basically consistent in magnitude, the power loss caused by the extra current injection can be regarded as low loss. Moreover, the drain current of the device under test 100 is caused to be large by the fact that the extra current is injected into the device under test 100, so that the device under test 100 has a faster turn-off speed, which also further reduces the total loss of the device under test 100 in the extra current injection stage.

### Wide Applicability

The energy storage element 204 in the online measurement circuit 200 will spontaneously inject current into the drain 103 of the device under test 100. The start time of injection is determined by the relationship between the voltage between the drain 103 and the source 104 of the device under test 100 and the voltage across the energy storage element 204. The injection process is spontaneous. The new generation of wide bandgap and ultra-wide bandgap semiconductor devices have extremely fast switching speed. If it is necessary to control the switching transient of devices in the process of online detection of the junction temperature of such semiconductor devices, higher precision and more complex control circuits will be required, which will further bring higher cost. However, the present disclosure is implemented without controlling the switching transient of the semiconductor devices, and has advantages such as simple control and low cost.

Finally, it should be noted that the above embodiments are only used to illustrate the technical solutions of the present disclosure and not intended to limit the technical solutions. Although the present disclosure has been described in detail with reference to the above embodiments, those skilled in the art should understand that modifications and equivalent replacements may still be made to the specific embodiments of the present disclosure, and any modification or equivalent replacement that does not deviate from the spirit and scope of the present disclosure should be included in the protection scope of the claims of the present disclosure.

What is claimed is:

1. A system for online detection of a junction temperature of a semiconductor device, comprising a controller, an online measurement circuit (200), and a detection module configured to extract saturated drain current information of a device under test (100), wherein one end of the online measurement circuit (200) is connected to a drain (103) of the device under test (100), and the other end of the online measurement circuit (200) is connected to a source (104) of the device under test (100);
when the device under test (100) enters a saturation region to operate, an energy storage element (204) in the online measurement circuit (200) spontaneously injects current into the drain (103) of the device under test (100), so that the drain current of the device under test (100) rises;
the controller is connected to the detection module, and determines the junction temperature of the device under test (100) according to the saturated drain current information of the device under test (100) extracted by the detection module.

2. The system for online detection of a junction temperature of a semiconductor device according to claim 1, further comprising a driving voltage control circuit (300), wherein one end of the driving voltage control circuit (300) is connected to a gate (101) of the device under test (100), the other end of the driving voltage control circuit (300) is connected to a Kelvin source (102) of the device under test (100), a control end of the driving voltage control circuit (300) is connected to the controller, and the controller controls the driving voltage control circuit (300) to output a driving voltage signal to the device under test (100), so that the device under test (100) enters the saturation region to operate.

3. The system for online detection of a junction temperature of a semiconductor device according to claim 1, wherein the online measurement circuit (200) comprises an energy storage element (204), a direct current (DC) voltage source (203), a controllable switching device (202) and a device with a unidirectional blocking function (201), wherein one end of the device with a unidirectional blocking function (201) is connected to the drain (103) of the device under test (100), the other end of the device with a unidirectional blocking function (201) is connected to one end of the energy storage element (204) and one end of the controllable switching device (202), the other end of the controllable switching device (202) is connected to a positive pole of the DC voltage source (203), and a negative pole of the DC voltage source (203) and the other end of the energy storage element (204) are connected to the source (104) of the device under test (100).

4. The system for online detection of a junction temperature of a semiconductor device according to claim 1, wherein the online measurement circuit (200) comprises an energy storage element (204), a pulsed DC source (205) and a device with a unidirectional blocking function (201), wherein one end of the device with a unidirectional blocking function (201) is connected to the drain (103) of the device under test (100), the other end of the device with a unidirectional blocking function (201) is connected to one end of the energy storage element (204) and a positive pole of the pulsed DC source (205), and a negative pole of the pulsed DC source (205) and the other end of the energy storage element (204) are connected to the source (104) of the device under test (100).

5. The system for online detection of a junction temperature of a semiconductor device according to claim 1, wherein the online measurement circuit (200) comprises an energy storage element (204) and a device with a unidirectional blocking function (201), wherein one end of the device with a unidirectional blocking function (201) is connected to the drain (103) of the device under test (100), the other end of the device with a unidirectional blocking function (201) is connected to one end of the energy storage element (204), and the other end of the energy storage element (204) is connected to the source (104) of the device under test (100).

6. The system for online detection of a junction temperature of a semiconductor device according to claim 5, wherein the energy storage element (204) is a capacitor.

7. A method for online detection of a junction temperature of a semiconductor device, based on the system for online detection of a junction temperature of a semiconductor device according to claim 1, and comprising:
enabling the device under test (100) to enter the saturation region to operate, and injecting, by the energy storage element (204) in the online measurement circuit (200), current into the drain (103) of the device under test (100) spontaneously after the device under test (100) enters the saturation region to operate, so that the drain current of the device under test (100) rises;
extracting the saturated drain current information of the device under test (100) by the detection module; and
determining the junction temperature of the device under test (100) according to the saturated drain current information of the device under test (100).

8. The method for online detection of a junction temperature of a semiconductor device according to claim 7, wherein the system for online detection of a junction temperature of a semiconductor device further comprises a driving voltage control circuit (300), wherein one end of the driving voltage control circuit (300) is connected to the gate (101) of the device under test (100), the other end of the driving voltage control circuit (300) is connected to the Kelvin source (102) of the device under test (100), and a control end of the driving voltage control circuit (300) is connected to the controller.

9. The method for online detection of a junction temperature of a semiconductor device according to claim 8, specifically comprising:
1. in the t₀-t₁ stage, a gate-source voltage V_{GS} of the device under test (100) being less than a threshold voltage, so that the device under test (100) is in an off state, indicating that the drain current I_{D} flowing into the device under test (100) is zero;
2. in the t₁-t₂ stage, the driving voltage control circuit (300) outputting a first driving voltage signal to the device under test (100), resulting in the gate-source voltage V_{GS} of the device under test (100) being higher than the threshold voltage, so that the device under test (100) is in a normal on state, indicating that the drain current I_{D} flowing into the device under test (100) rises;
3. in the t₂-t₃ stage, the gate-source voltage V_{GS} of the device under test (100) being less than the threshold voltage, so that the device under test (100) changes from the on state to the off state, indicating that the drain current I_{D} flowing into the device under test (100) is zero;
4. in the t₃-t₄ stage, the gate-source voltage V_{GS} of the device under test (100) being less than the threshold voltage, so that the device under test (100) continues to be maintained in the off state, indicating that the drain current ID flowing into the device under test (100) is zero, in which case an energy storage element charging control signal V_{M} is activated for charging the energy storage element (204) in the online measurement circuit (200);
5. in the t₄-t₅ stage, the energy storage element (204) in the online measurement circuit (200) having started to be charged, so that the energy storage element charging control signal V_{M} is deactivated; the gate-source voltage V_{GS} of the device under test (100) being less than the threshold voltage, so that the device under test (100) continues to be maintained in the off state, indicating that the drain current I_{D} flowing into the device under test (100) is zero;
6. in the t₅-t₆ stage, the driving voltage control circuit (300) outputting a second driving voltage signal, so that a voltage between the drain (103) and the source (104) of the device under test (100) gradually drops from a DC bus voltage to a voltage across the energy storage element (204) in the online measurement circuit (200), and the drain current flowing into the device under test (100) rises; enabling the energy storage element charging control signal V_{M} to be not activated;
7. in the t₆-t₇ stage, the driving voltage control circuit (300) outputting the second driving voltage signal to the device under test (100), and since the voltage across the energy storage element (204) is higher than a voltage between the gate (101) and the Kelvin source (102) of the device under test (100), the device under test (100) entering the saturation region to operate, and the energy storage element (204) in the online measurement circuit (200) starting to spontaneously inject current into the drain (103) of the device under test (100), so that the drain current of the device under test (100) rises; extracting the saturated drain current information of the device under test (100) by the detection module, and determining the junction temperature of the device under test (100) according to the saturated drain current information of the device under test (100);
8. in the t₇-t₈ stage, the gate-source voltage V_{GS} of the device under test (100) being less than the threshold voltage, so that the device under test (100) enters the off state, indicating that the drain current I_{D} flowing into the device under test (100) is zero; enabling the energy storage element charging control signal V_{M} to be not activated.

10. A controller, comprising:
a control module, configured to enable a device under test (100) to enter a saturation region to operate, and inject, by an energy storage element (204) in an online measurement circuit (200), current into a drain (103) of the device under test (100) spontaneously after the device under test (100) enters the saturation region to operate, so that the drain current of the device under test (100) rises;
an extracting module, configured to extract saturated drain current information of the device under test (100) by a detection module; and
a determining module, configured to determine a junction temperature of the device under test (100) according to the saturated drain current information of the device under test (100).
